(19) United States
(12) Patent Application Publication
(10) Pub. No.: US 2005/0205971 A1
(43) Pub. Date: Sep. 22, 2005

(54) Holiday Light String Devices

(75) Inventor: John L. Janning, Dayton, OH (US)

Correspondence Address: MARC FILIGENZI, 315 E. MONTGOMERY, SPOKANE, WA, 99207, US

(73) Assignee: JLJ, INC., Dayton, OH (US)

(21) Appl. No.: 10/908,866

(22) Filed: May 30, 2005

Related U.S. Application Data
(63) Continuation-in-part of application No. 10/908,365, filed on May 9, 2005.
(63) Continuation-in-part of application No. 10/611,744, filed on Jul. 1, 2003.
(60) Provisional application No. 60/471,094, filed on May 16, 2003.

(51) Int. Cl. H01L 23/495

(52) U.S. Cl. 257/666

(57) ABSTRACT

Light strings in which a semiconductor device or chip is wired across a light socket in a series-wired light string are described. The device or chip is packaged in a cavity in a spacer, e.g., a through hole, in a non-conductive spacer, e.g., a sheet construction with a cavity housing the chip. The chip has a pair of opposite faces forming electrodes connecting with electrode contacts, e.g., contact sheets, on opposite sides of the non-conductive spacer. The contacts are pinched between or otherwise connect with contacting elements inside the light string socket.

### CROSS-REFERENCE TO RELATED APPLICATIONS

This is a continuation-in-part of co-pending U.S. patent application Ser. No. 10/908365 filed May 9, 2005, and is further a continuation-in-part of co-pending U.S. patent application Ser. No. 10/611,744 filed Jul. 1, 2003 which claims the priority benefit of U.S. Provisional Application No. 60/471094 filed May 16, 2003.

### BACKGROUND

Packaging of semiconductor devices such as chips used as electrical shunts adds cost to Christmas and other holiday season light stings in which the devices are used. By way of example, shunts typically in the form of one or more diodes are used in series-wired incandescent mini-light strings to provide an alternative pathway for current when a bulb burns out or is missing from or loose in its socket. Such a shunt, typically wired across each mini-light socket, may comprise back-to-back Zener diodes as used in Stay-Lit® type light strings and described in U.S. Pat. No. 6,580,182, or a single Zener diode as described in U.S. Pat. No. 6,765,313, or a diode array as described in U.S. Pat. No. 6,084,357, on a semiconductor chip.

It is customary for semiconductor chips, such as diodes or other discrete devices, to be packaged or housed in a plastic or glass body with wire leads coming out of each end. There are also packages where the leads are flat and more-or-less “inline” so as to make the package more easily connectable via soldering onto printed circuit boards.

Typical shunt devices, e.g., in the form of back-to-back Zener diode chips (dice) with approximate dimensions of 0.032″×0.032″×0.018,″ have been contained for example in DO-41 type axial-leaded plastic packaging. This is basically a tubular packaging construction of approximately 0.205″ in length and approximately 0.107″ diameter with conductive leads protruding from each end of the plastic package.

Given the number of lighting elements in a Christmas or other holiday light string, e.g., 50 to 100 lights in a Stay-Lit® type light string, a small cost differential per lighting element for packaging can make a significant pricing difference per string.

### SUMMARY

Light strings in which a semiconductor device or chip is wired across a light socket in a series-wired light string are described. The device or chip is packaged in a cavity in a spacer, e.g., a through hole, in a non-conductive spacer, e.g., a sheet construction with a cavity housing the chip. The chip has a pair of opposite faces forming electrodes connecting with electrode contacts, e.g., contact sheets, on opposite sides of the non-conductive spacer. The contacts are pinched between or otherwise connect with contacting elements inside the light string socket.

Additional variations, features and advantages will become apparent from the further related description and drawings, and the claims to follow.

### BRIEF DESCRIPTION OF THE DRAWINGS

FIG. 1 shows a Christmas or other holiday season light string on a tree.

FIG. 2 shows a schematic of a series wired incandescent holiday season light string with semiconductor shunt devices wired across each light string socket.

FIG. 3A shows a single cavity unit assembly with conductive epoxy on electrode contact sheets, along with the chip to be packaged.

FIG. 3B shows the single cavity unit of FIG. 3A, partially assembled, with one electrode contact sheet installed.

FIG. 3C shows the single cavity unit of FIG. 3B, partially further assembled, with the chip to be packaged installed.

FIG. 3D shows the single cavity unit of FIG. 3C, fully assembled, with two electrode contact sheets and the chip to be packaged installed.

FIG. 4A shows a packaged chip assembly pinched or wedged between electrical contacting elements inside a light bulb socket in a holiday season light string.

FIG. 4B shows a socket of a lighting element assembly across which a packaged electrical shunt chip is connected by electrical contacting elements having prominences that contact the electrode contact sheets of the packaged chip.

FIG. 5 shows a single cavity unit assembly with electrode contact sheets “dimpled” to provide electrode contacting prominences on sides shown facing the cavity.

FIG. 6 shows a single cavity unit assembly with “dimpled” electrode contact sheets, with one electrode contact sheet being in the form of a c-clip.

FIG. 7 shows multiple cavity units in a single spacer sheet structure before breaking apart into provide single packaged units.

FIG. 8 shows the patterning on a double sided clad thin printed circuit board used to provide a spacer structure with multiple cavities for multiple packaged devices.

FIG. 9 shows an enlarged view of a cavity shown in FIG. 8, showing relief of cladding to ensure non-conductivity of structure in the vicinity of the cavity.

### DESCRIPTION

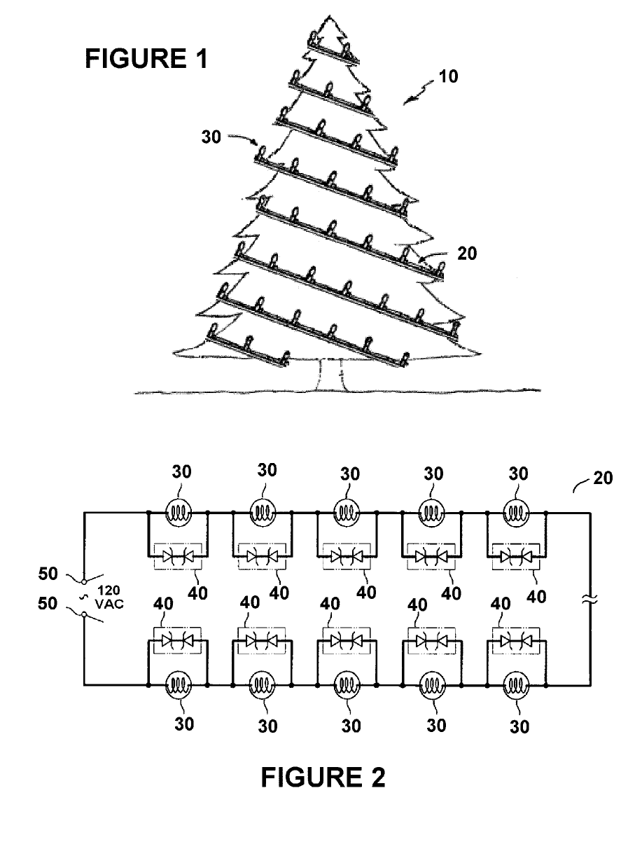

FIG. 1 shows a tree 10 draped with a traditional Christmas or other holiday season light string 20, comprising series-wired incandescent low voltage lighting elements such as now standard mini-lights 30. FIG. 2 shows a schematic of a 120 VAC light string 20 of the Stay-Lit® type in which an electrical shunt 40 is wired across the bulb socket of each lighting element 30. The illustrated shunt 40 provides an alternative pathway for current and a controlled voltage drop across the socket if the lighting element 30 becomes inoperative or electrically disconnected from the socket. If a lighting element 30 goes out or becomes loose in or missing from its socket, other lighting elements 30 in the string 20 will remain lit as described in U.S. Pat. No. 6,580,182.

The shunts 40 shown in FIG. 2 comprise back-to-back Zener diodes as taught in U.S. Pat. No. 6,580,182, but other devices can be used such as a single Zener diode as taught in U.S. Pat. No. 6,765,313, or a diode array as taught in U.S. Pat. No. 6,084,357. A typical shunt 40 is implemented in the form of a small semiconductor chip that requires packaging to facilitate its incorporation into a light string 20. While the packaged devices 40 have generally been inexpensive their cost can add significantly to the overall cost of a light string 20 in which 50-100 lighting elements 30 are used.

It is has been customary for semiconductor chips, such as discrete diodes, to be packaged—or housed—in a plastic body with wire leads coming out of each end. There are also packages where the leads are flat and more-or-less “inline” so as to make it more easily connectable via soldering onto a printed circuit board. The cost of the packaging has been high compared with the cost of a chip such as a small Zener diode or other small silicon rectifier diodes being packaged.

By way of illustration, back-to back Zener diode shunts 40 have been implemented in 0.032″×0.032″×0.018″ semiconductor chips (dice) inside DO-41 type plastic packaging. Such packaging typically comprises a tubular construction of approximately 0.205″ in length and approximately 0.107″ in diameter with leads protruding from each end of the package. Electrical connection to such a chip in a DO-41 package is made by connecting the leads to opposite sides of the chip.

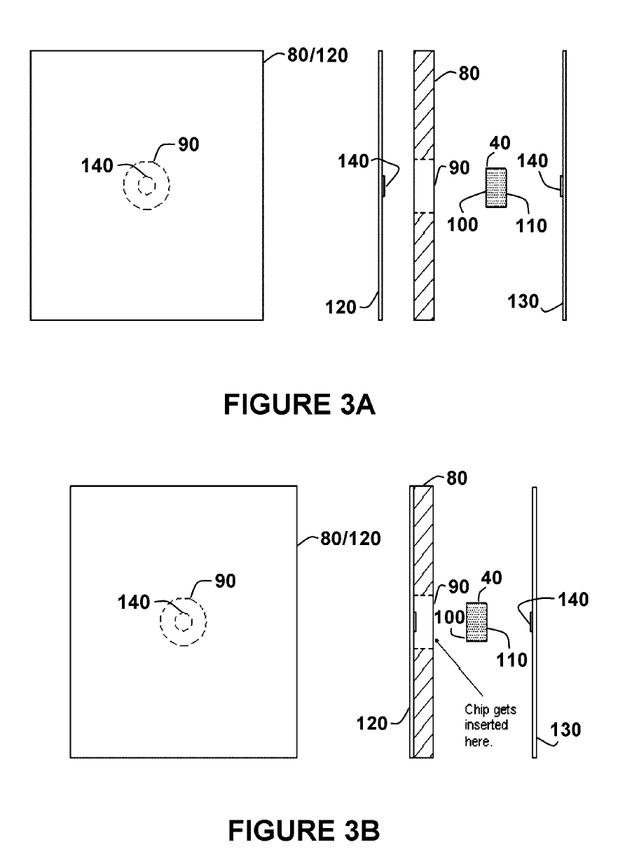

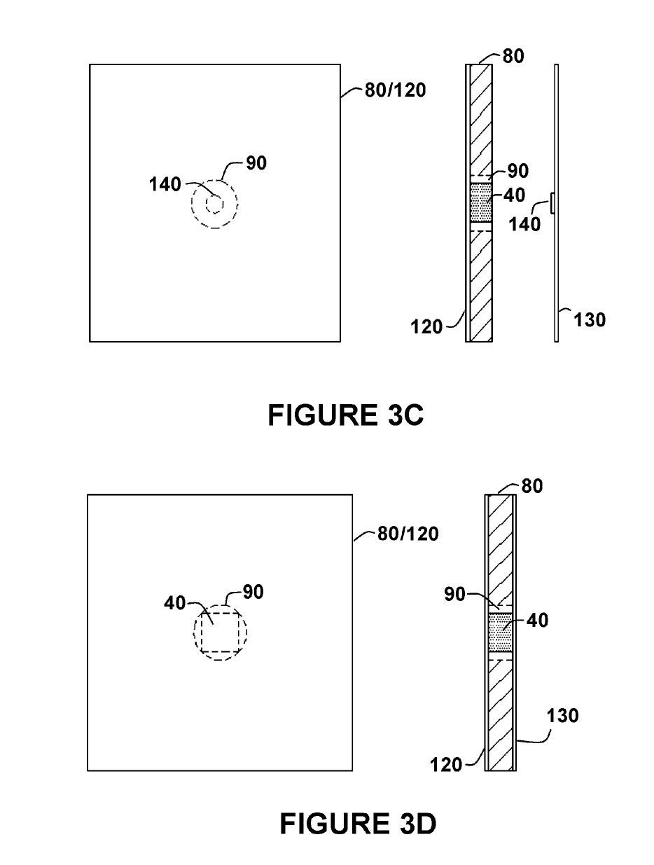

Referring to FIG. 3A, a packaging assembly is shown comprising a plastic or other non-conductive sheet or spacer 80 having a cavity 90 for housing a semiconductor chip 40. The chip 40 has opposite faces 100 and 110 respectively forming two electrodes for the chip 40. The illustrated assembly also includes a pair of electrically conductive sheets or electrode contacts 120 and 130 which connect with the electrode faces 100 and 110 when the package is assembled. The electrode contact sheets 120 and 130 are shown with spots of electrically conductive epoxy 140 to bond with the electrode faces 100 and 110 for electrical contact. When assembled the resulting construction is one, e.g., in which the chip 40 is housed in a cavity 90 in a plastic sheet 80, where on both sides of the cavity 90, there are secured electrode contacts 120 and 130, in the form of thin sheets of metal, for making electrical contact to the chip 40. The construction is thus a sandwich consisting of two metal contact sheets 120 and 130 with a non-conductive spacer sheet 80 in-between containing a cavity 90 where the chip 40 resides. While this assembly does not have wire terminals, it does provide for connection between two spring-like contacts or other interconnection inside the socket for a lighting element 30. This makes it quite attractive for use inside a mini-light socket as a shunt 40.

FIG. 3B illustrates the assembly elements shown in FIG. 3A with electrode contact sheet 120 installed or affixed to the non-conductive spacer 80. As shown the electrode contact 120 is in the form of a thin metal sheet, e.g., on the order of approximately a few thousandths of an inch thick or less, secured to one side of the plastic sheet 80 containing a cavity 90 by an adhesive applied to the affixed side of the plastic sheet 80 with pressure applied. The tiny semiconductor chip 40 is then placed inside of the cavity 90 in an upright position so that one electrode side 100 of the chip is facing and touching the electrically conductive epoxy 140 applied to thin metal sheet 120, as shown in FIG. 3C. Electrode contact 130, e.g., a second thin metal sheet, is then placed over this assembly and likewise secured by an adhesive previously applied to the plastic sheet 80, with pressure applied. Electrical connection to the electrode 110 of the chip 40 facing the electrode contact 130 is similarly established with a spot of electrically conductive epoxy 140 as shown in FIG. 3C. The packaged chip 40 as shown in FIG. 3D is now ‘housed’ in the new package with the chip's electrodes in contact with the thin metal sheets 120 and 130 that are on the outside of the new package structure.

The cavity 90 is preferably dimensioned to house the semiconductor chip 40 to fit within the cavity 90 without interference only when electrodes 100 and 110 of the chip 40 are correctly positioned to face and electrically contact the electrode contact sheets 120 and 130. This helps ensure the chip 40 will be correctly assembled inside the cavity 90.

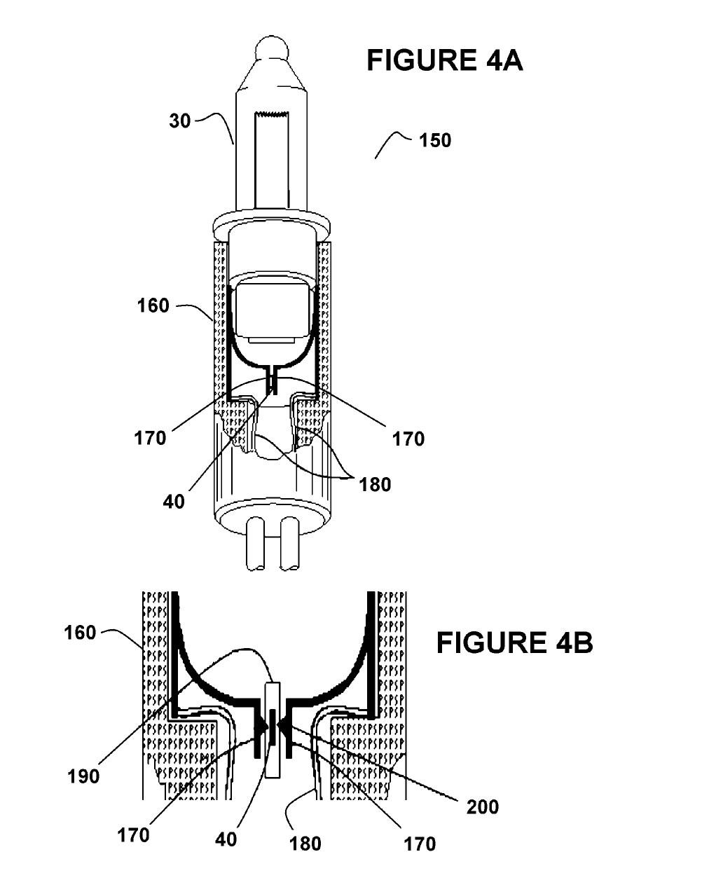

FIG. 4A illustrates the packaged semiconductor shunt chip 40 incorporated into a holiday season lighting element assembly 150 comprising a socket 160 for an incandescent mini-light bulb and base unit 30, with the chip 40 being electrically connected across the lead connections 180 of the socket 160. As shown, the chip 40 is situated inside the socket 160 between electrical contacting elements 170 inside the socket. The chip 40 is situated inside a cavity 90 in a non-conductive spacer 80 between opposed electrode contacts 120 and 130 as shown in FIGS. 3A-3D. The electrical contacting elements 170 are spring-like elements between which the electrode contacts 120 and 130 are pinched or wedged for electrical connection. Other means of electrical connection such as soldering could be used. FIG. 4B shows alternative structure inside a socket 160 where packaging 190 containing chip 40 is situated between contacting elements 170 having points or prominences 200 by which electrical contact with electrode contacts 120 and 130 is enhanced.

To ensure good electrical contact between the chip 40 and outer thin metal sheets 120 and 130, a tiny amount of a conductive epoxy 140 could be silk-screened onto the center of the thin metal sheets 120 and 130 before they are secured to the plastic sheet 80 containing the housing cavity 90, as shown in FIGS. 3A-3D. After the assembly is finished, a few hours may be needed for the epoxy to cure, thus bonding the chip 40 and thin metal 120 and 130 sheets together.

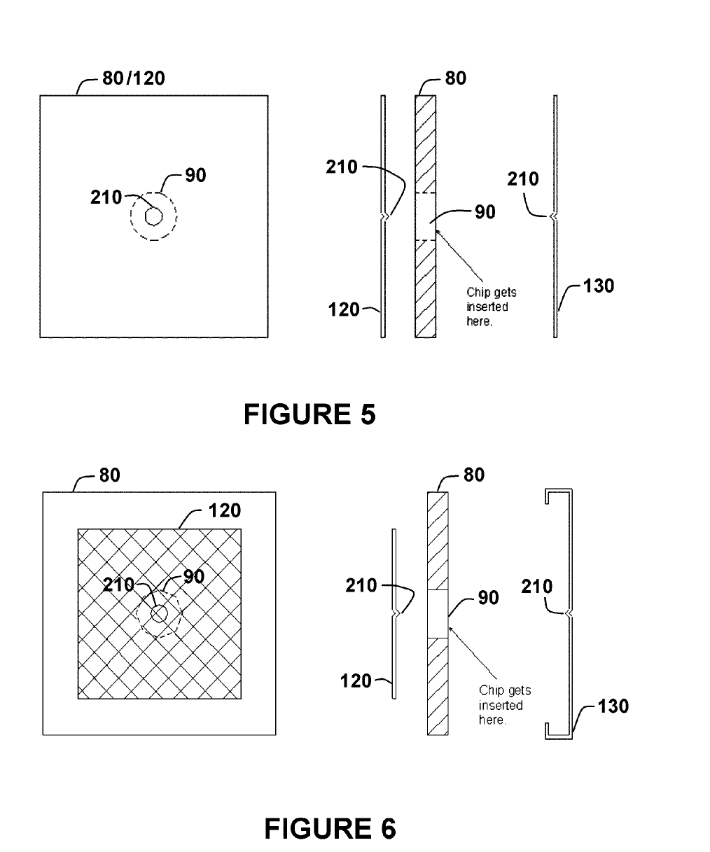

Another means of making contact from thin metal sheets 120 and 130 to the chip 40 is to form a small “dimple” in the thin metal sheet producing a point or prominence 210 protruding inward to contact the chip. This is shown in FIG. 5. Using a tinned copper sheet (or other solderable metal) for the thin of metal sheets 120 and 130, and a chip 40 with “solder bumps”, the chip dice could easily be soldered to the thin metal sheets by applying heat to the assembly with pressure applied to the outside electrode contacts 120 and 130. However, if soldering is to be done, the plastic for the spacer 80 should be able to withstand the heat without undue deformation. As shown in FIG. 6 one or both of the electrode contacts 120 and 130 are in the form of a c-clip for mechanical attachment to the non-conductive spacer 80. Electrode contacts 120 and 130 are “dimpled” and have prominences or points by which to contact electrode faces 100 and 110 of chip 40.

Also, in any of the packaging fabrication methods, the plastic selected for the spacer 80 could be one that is somewhat porous so that it can “breathe” if the chip 40 gets too hot during operation. In air-tight assemblies in which there was no bonding agent such as solder or conductive epoxy 140 connecting the chip 40 with the electrode contacts 120 and 130, a “flasher” phenomenon has been observed. With reliance only on touch contact between the chip 40 and contacts 120 and 130, the packaged chip 40 performs as a flasher as opposed to a continuously operating shunt when the associated mini-light is pulled out of its socket 160 or burns out or does not work for some reason. Current flows then through the semiconductor device 40 causing the chip 40 to get hot, pressurizing the confined surrounding air. The increased air pressure moves copper electrode contacts 120 and 130 away from the chip 40, disconnecting it. When the chip 40 is no longer connected, it cools and contact to the contacts 120 and 130 is again made. This cycle repeats and produces a repeatable flashing of the remaining lights 30 in the light string 20.

Depending upon the method of fabrication used, the electrode contacts 120 and 130 are preferably thin metal copper sheet but other metals may also be used such as aluminum, brass, bronze, steel or other preferably low cost metal.

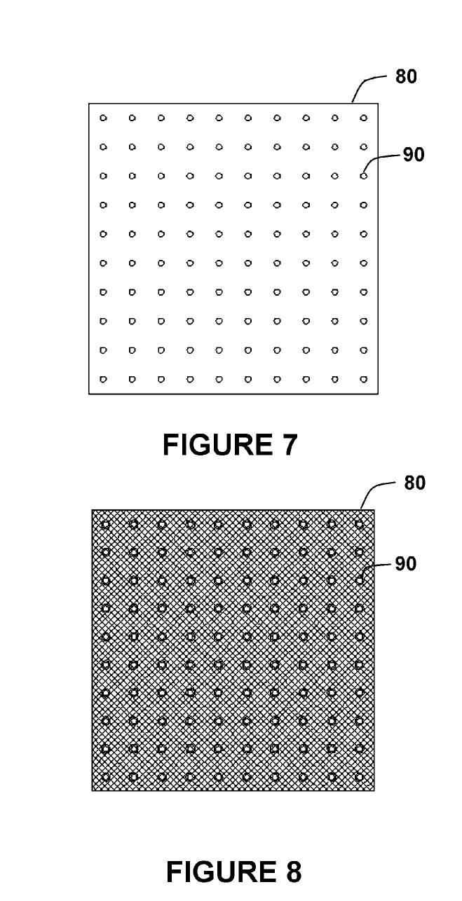

FIG. 7 shows how multiple ‘housing’ cavity 90 units might be constructed in a single spacer sheet 80. Shown are round cavities 90 but square cavities 90 could also be used. After fabrication, the multi-unit assembly would then be cut into discrete units of packaged chips 40. A unit 40 would then be placed inside of a Christmas mini-light socket between two spring-like prongs 170 for electrical connection as shown in FIGS. 4A-B. While such a structure is preferably suited for use in Christmas tree light sockets, there exist other applications where a low cost packaging structure such as described here would be quite useful and desired.

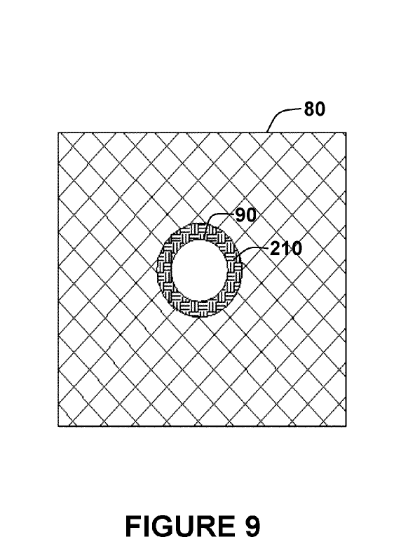

FIGS. 8 and 9 show the use of a thin printed circuit type board 80 with copper cladding on both sides. Copper is etched away in the area 210 of the holes 90 followed by holes 90 being formed in the center of where the copper has been removed in a 100 unit array. After chip 40 insertion, the “end conductor plates” 120 and 130 are attached as before. However, in this case, where a conductive material is applied over a conductive material, conductive adhesive might preferably be used. Also, low temperature solder could be used to secure the outer conductor plates 120 and 130 to the cladding of the board 80 to make the assembly. As shown in FIG. 9 the area 210 around the hole 90 is free from metal and therefore non-conductive, to prevent silicon wafer body material of the chip 40 from electrically shorting.

While the foregoing description presents the invention in general terms and in terms of specific examples, many variations are possible which are not described here. All such variations of the invention are also within the scope of the following claims.

1. A packaged electrical device, comprising: a non-conductive spacer having a cavity; a semiconductor device situated in said cavity; and a pair of electrode contacts electrically contacting said semiconductor device on opposite sides of said spacer.

2. A holiday season lighting element assembly comprising a socket for an incandescent mini-light bulb and an electrical shunt implemented by a semiconductor chip connected across the socket, said chip being situated within a cavity in a non-conductive spacer between opposed electrode contacts for the chip, said electrode contacts being situated between electrical contacting elements inside the socket.

3. The lighting element assembly of claim 2 in which said electrode contacts are pinched or wedged between said electrical contacting elements to provide electrical connection.

4. A packaged electrical device, comprising: a semiconductor device having opposite faces respectively forming two electrodes; a pair of electrically conductive electrode contacts sandwiching the semiconductor device and electrically contacting the two electrodes; and an electrically non-conductive spacer affixed between the electrode contacts and having a cavity in which the semiconductor device is situated.

5. The packaged semiconductor device of claim 4 in which at least one of the electrode contacts is a metal c-clip affixed to the spacer by spring action of the c-clip.

6. A packaged electrical device, comprising: a semiconductor device having opposite faces respectively forming two electrodes; a pair of metal electrode contact sheets sandwiching the semiconductor device and electrically contacting the two electrodes; and an electrically non-conductive spacer sheet affixed between the electrode contact sheets and having a cavity in which the semiconductor device is situated.

7. The packaged electrical device of claim 6 in which the electrode contact sheets are each affixed to the spacer sheet by an adhesive.

8. The packaged electrical device of claim 6 in which the cavity is a through hole.

9. The packaged electrical device of claim 6 in which the electrode contact sheets are bonded to the electrodes of the semiconductor device by a conductive epoxy.

10. The packaged electrical device of claim 6 in which the electrode contact sheets have prominences which electrically contact the electrodes of the semiconductor device.

11. The packaged electrical device of claim 6 in which the electrode contact sheets are soldered to the electrodes of the semiconductor device.

12. The packaged electrical device of claim 11 in which the electrode contact sheets have prominences to which the electrodes of the semiconductor device are soldered.

13. The packaged electrical device of claim 6 in which said cavity is dimensioned to house the semiconductor device to fit within said cavity without interference only when said electrodes are correctly positioned to face and electrically contact said electrode contact sheets.

14. The packaged electrical device of claim 6 in which the spacer sheet has a copper cladding on both sides, where said cladding is relieved from around the perimeter edges of said cavity to avoid shorting said semiconductor device, and where the electrode contact sheets are affixed to said cladding by an electrically conductive adhesive.

15. A method of constructing a packaged electrical device, steps of which comprise: securing a first metal electrode contact sheet to said one side of a plastic spacer sheet with a pressure sensitive adhesive; placing a semiconductor chip in a cavity in said spacer sheet, said chip having opposite faces respectively forming two electrodes, one of said electrodes being placed to face and contact said first metal electrode contact sheet; and securing a second metal electrode contact sheet to the other side of said plastic spacer sheet with a pressure sensitive adhesive, said second metal electrode contact sheet being placed to face and contact the other of said electrodes of said semiconductor chip.

16. The method of claim 15 in which said electrodes are respectively electrically bonded to the first and second metal electrode contact sheets by conductive epoxy silk-screened onto said electrode contact sheets.

17. The method of claim 15 in which the semiconductor chip electrodes are respectively provided with solder bumps and are electrically bonded to the first and second metal electrode contact sheets by soldering, where said electrode contact sheets comprise a tinned copper or other solderable metal, and where said electrode contact sheets are dimpled to produce prominences on said electrode contact sheets to which said electrodes are soldered.

18. The method of claim 15 in which multiple packaged electrical devices are produced placing a semiconductor chip in each of multiple cavities in said spacer sheet, where said first and second metal electrode contact sheets are secured to opposite sides of said spacer sheet in electrical contact with electrodes of each of said semiconductor chips.

19. The method of claim 18 in which said packaged electrical devices are separated from one another by breaking along score lines in at least one of said electrode contact sheets.

20. The method of claim 18 in which said packaged electrical devices are separated from one another by cutting or sawing.

21. The method of claim 15 in which said spacer sheet has a copper cladding on both sides, where said cladding is relieved from around the perimeter edges of said cavity to avoid shorting said semiconductor chip, and where said electrode contact sheets are affixed to the cladding by an electrically conductive adhesive.

22. A holiday season light string in which light bulbs are fitted in series wired sockets, there being an electrical shunt across each of said sockets, each of said shunts being implemented by a semiconductor chip connected across the socket, said semiconductor chip being situated within a cavity in a spacer between opposed electrode contacts for the chip, said electrode contacts being situated between electrical contacting elements inside the socket.
